(19) United States
(12) Patent Application Publication
(10) Pub. No.: US 2007/0098188 A1
(43) Pub. Date: May 3, 2007

(54) Equalization setting determination for audio devices

(76) Inventor: Matthew D. Felder, Austin, TX (US)

Correspondence Address: GARLICK HARRISON & MARKISON, P.O. BOX 160727, AUSTIN, TX, 78716-0727, US

(21) Appl. No.: 11/265,047

(22) Filed: Nov. 2, 2005

(51) Int. Cl. H03G 3/00; H03G 5/00

(52) U.S. Cl. 381/107; 381/103; 381/104

(57) ABSTRACT

A method for reducing distortion caused by clipping of lower frequency audio signals begins by monitoring a volume setting of an audio signal with respect to a range of volume settings to produce a monitored volume setting. The method continues by establishing an equalization setting based on the monitored volume setting.

### CROSS REFERENCE TO RELATED PATENTS

NOT APPLICABLE

### STATEMENT REGARDING FEDERALLY SPONSORED RESEARCH OR DEVELOPMENT

NOT APPLICABLE

### INCORPORATION-BY-REFERENCE OF MATERIAL SUBMITTED ON A COMPACT DISC

NOT APPLICABLE

### BACKGROUND OF THE INVENTION

1. Technical Field of the Invention

This invention relates generally to audio devices and more particularly to audio processing.

2. Description of Related Art

As is known, the audio frequency spectrum is from approximately 20 Hz to 20 KHz and that the human ear is “tuned” to about 1 KHz (i.e., audio signals at 1 KHz are more easily heard than audio signals at the same power level, but at the edges of the audio frequency spectrum). While this is the natural occurrence of human reception of audio signals, audio playback devices attempt to provide audio signals throughout the audio frequency spectrum at levels for humans to hear as easily as we hear audio signals around 1 KHz.

One technique that audio playback devices (e.g., CD players, MP3 players, radio, computer audio codecs, etc.) utilize to provide more uniform perception of audio signals is non-linear quantization when converting between analog audio signals and digital audio signals. As is known, a non-linear quantization system may be generally viewed as a linear system having a compander added thereto. In such a system, an analog audio signal is first compressed using a non-linear law (e.g., A-law, μ-law) to produce a non-linear compressed signal and then linearly quantized to produce a digital audio signal. To convert a digital audio signal into an analog audio signal, the reverse process is followed using an inverse of the non-linear law.

In addition to non-linear quantization, many audio devices provide equalization. In a basic audio device, equalization is achieved by dividing the audio frequency spectrum into at least two regions (e.g., bass and treble). For each region, the user of the audio device may set the equalization level (i.e., the gain for the corresponding frequency spectrum) to make the signals within the region more or less perceivable to the human ear. In more complex audio devices, the audio frequency spectrum is divided into more than two regions with user control to set the equalization for each region.

A conflict arises with battery powered audio devices between providing maximum audio outputs over the audio frequency spectrum and battery life extension. As is generally known, battery life of a battery powered audio device is extended by reducing power consumption, which is at least partially achieved by reducing the operating voltage of audio device. This, however, may cause audio output drivers to clip when equalization and/or volume settings are set at near maximum levels. Such clipping is most problematic for bass signals (i.e., audio signals in lower portion of the audio frequency spectrum), which, when clipped, produce distortion within the audio frequency spectrum. Such distortion reduces the signal quality of the audio device.

Therefore, a need exists for a method and apparatus for automatically reducing the potential of distortion caused by clipping of lower frequency audio signals.

### BRIEF DESCRIPTION OF THE SEVERAL VIEWS OF THE DRAWING(S)

FIG. 1 is a schematic block diagram of an audio device in accordance with the present invention;

FIG. 2 is a schematic block diagram of another audio device in accordance with the present invention;

FIG. 3 is a graph of human perceptibility of an audio signal spectrum;

FIGS. 4-8 are frequency spectrum graphs of equalization settings in accordance with various embodiments of the present invention; and

FIG. 9 is a schematic block diagram of an audio output stage in accordance with the present invention.

### DETAILED DESCRIPTION OF THE INVENTION

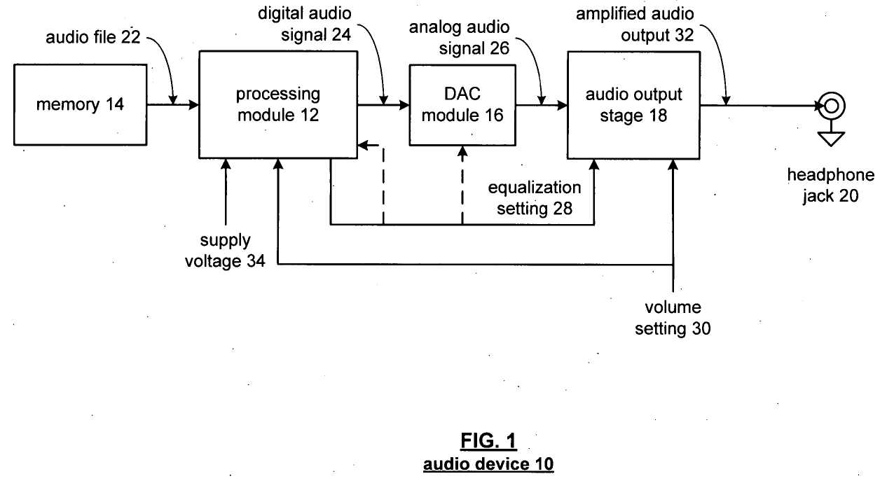

FIG. 1 is a schematic block diagram of an audio device 10, which may be included in an MP3 player, a computer audio system, a CD player, a television audio output, a DVD audio player, et cetera. The audio device 10 includes memory 14, a processing module 12, a digital-to-analog conversion (DAC) module 16, an audio output stage 18 and a headphone jack 20. The processing module 12 may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on operational instructions. The memory 14 may be a single memory device, a plurality of memory devices, and/or embedded circuitry of the processing module. Such a memory device may be a read-only memory, random access memory, volatile memory, non-volatile memory, static memory, dynamic memory, flash memory, cache memory, and/or any device that stores digital information. Note that when the processing module 12 implements one or more of its functions via a state machine, analog circuitry, digital circuitry, and/or logic circuitry, the memory storing the corresponding operational instructions may be embedded within, or external to, the circuitry comprising the state machine, analog circuitry, digital circuitry, and/or logic circuitry. Further note that, the memory 14 stores, and the processing module 12 executes, operational instructions corresponding to at least some of the steps and/or functions illustrated in FIGS. 1-9.

In operation, the processing module 12 retrieves audio files 22 from memory 14. The audio files 22 may be stored in an MP3 format, a DVD audio format, a WMA format, and/or any other type of audio encoding protocol. The processing module 12 decodes, in accordance with a particular encoding protocol, the audio files 22 to produce digital audio signals 24.

The processing module 12 also generates an equalization setting 28 to avoid low frequency distortion of the audio output 32. In one embodiment, the processing module 12 generates the equalization setting 28 by monitoring a volume setting 30 with respect to a range of volume settings to produce a monitored volume setting. The processing module 12 then establishes the equalization settings 28 based on the monitored volume setting. For example, the volume setting 30 may correspond to a 5-bit digital signal (e.g., a digital counter of an up/down switch). As such, the volume setting 30 may be one of thirty-two values. If the largest digital value corresponds to the maximum volume setting, then there is a volume setting below the maximum setting where clipping of the audio output may occur, thus producing low frequency distortion. At this volume setting, and for volume settings above this setting to the maximum setting, the processing module generates the equalization setting 28 such that clipping of the lower frequency components of the audio output 32 is substantially avoided, thereby avoiding the low frequency distortion.

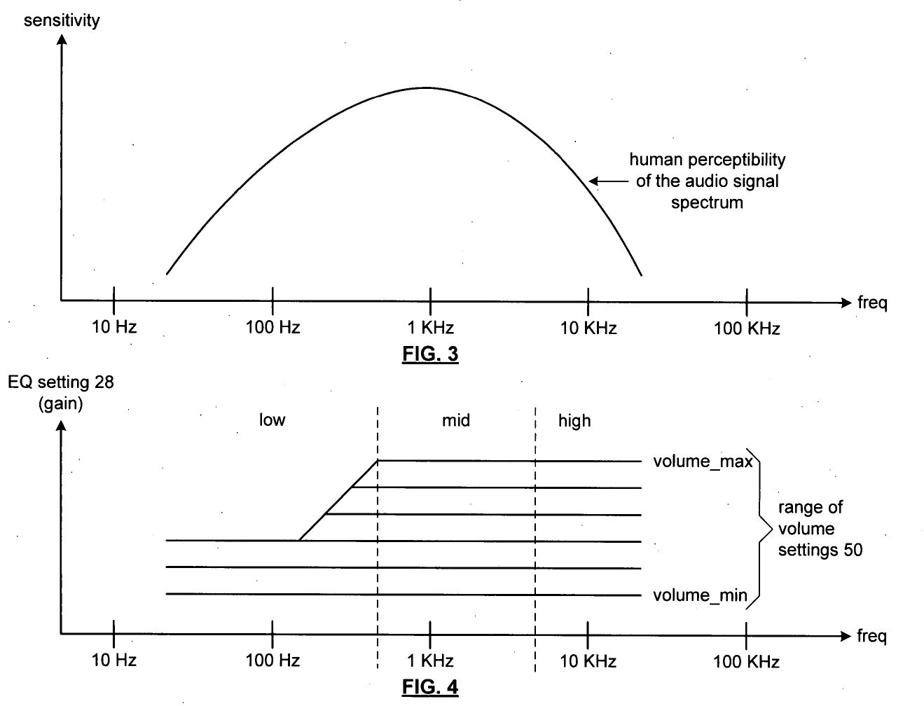

In another embodiment, the processing module 12 may use the supply voltage 34 in additional to the volume setting 30 to generate the equalization setting 28. In this embodiment, the processing module 12 uses the supply voltage 34 to determine whether the “volume setting threshold” as discussed in the example of the preceding paragraph should be adjusted. If the supply voltage 34 is nominal (e.g., 1.5 Volts to 3.3 Volts dependent on the fabrication process of the components of the audio device 10), the volume setting threshold is not adjusted for generating the equalization setting. If, however, the supply voltage 34 is less than nominal, the audio output is more likely to clip and produce noticeable low frequency distortion at the volume setting threshold, thus it is decreased. If the supply voltage is greater than nominal, the audio output is less likely to clip and produce noticeable low frequency distortion at the volume setting threshold, this it may be increased. The generation of the equalization setting 28 will be described in greater detail with reference to FIGS. 3-8.

The digital-to-analog conversion module 16 converts the digital audio signals 24 into analog audio signals 26 and provides the analog audio signals 26 to the audio output stage 18. The audio output stage 18, which may include one or more amplifiers and/or drivers, converts the analog audio signal 24 into the amplified audio output 32 based on the equalization setting 28 and the volume setting 30. In one embodiment, the audio output stage 18 provides the amplified audio output 32, which may be a monotone signal, a stereo signal and/or a surround sound signal, to one or more headphone jacks 20. In other embodiments, the audio output stage 18 may provide the amplified audio output 32 to one or more speakers. If the audio output stage 18 is providing the amplified audio output 32 to a single speaker, the audio output stage 18 may mix a left and right channel of a stereo signal to produce a monotone signal.

In an alternative embodiment, the processing module 12 may provide the equalization setting 28 to the DAC module 16. In this embodiment, the DAC module 16 converts the digital audio signal 24 into the analog audio signal 26 based on the equalization setting 28 such that the low frequency components of the audio signal are scaled in accordance with the equalization setting 28 to avoid low frequency distortion. In another embodiment, the processing module 12 may utilize the equalization setting 28 to scale low frequency components of the digital audio signal 24 to avoid the low frequency distortion.

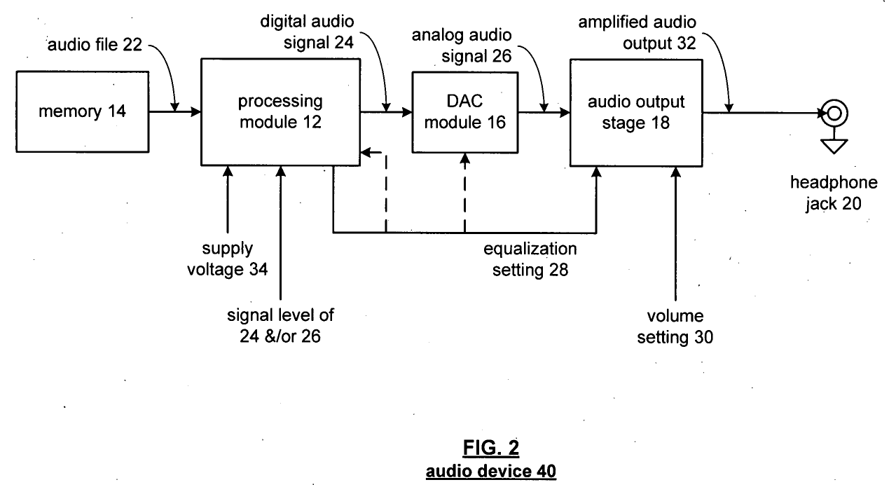

FIG. 2 illustrates a schematic block diagram of another audio device 40 that may be included in an MP3 player, a computer audio system, a CD player, a television audio output, a DVD audio player, et cetera. The audio device 10 includes the processing module 12, memory 14, DAC module 16, audio output stage 18, and headphone jack 20. In this embodiment, the processing 12 decodes audio files 22 to produce the digital audio signals 24; the DAC module 16 converts the digital audio signals 24 into the analog audio signals 26; and the audio output stage 18 amplifies the analog audio signals 26 based on the equalization setting 28 and the volume setting to produce the amplified audio output 32 as discussed with reference to FIG. 1.

In this embodiment, the processing module 12 generates the equalization setting 28 based on a signal level of the digital audio signal 24 and/or of the analog audio signal 26. To begin, the processing module 12 monitors the signal level of the digital audio signal 24 and/or the signal level of analog audio signal 26 to produce a monitored signal level. Note that the processing module 12 may monitor the signal level of the low frequency components of the signal 24 and/or 26 to produce the monitored signal level. The processing module 12 compares the monitored signal level with a low frequency distortion threshold (e.g., a signal level at which low frequency distortion might occur) to determine if the amplified audio output 32 might clip. If so, the processing module 12 generates the equalization setting 28 to scale the low frequency components of the amplified audio output 32, the digital audio signal 24, and/or the analog audio signal 26 to substantially avoid low frequency distortion.

In another embodiment, the processing module 12 may use the supply voltage 34 in additional to the signal level to generate the equalization setting 28. In this embodiment, the processing module 12 uses the supply voltage 34 to determine whether the low frequency distortion threshold should be adjusted. If the supply voltage 34 is nominal, the low frequency distortion threshold is not adjusted for generating the equalization setting. If, however, the supply voltage 34 is less than nominal, the audio output is more likely to clip and produce noticeable low frequency distortion at the low frequency distortion threshold, thus it is decreased. If the supply voltage is greater than nominal, the audio output is less likely to clip and produce noticeable low frequency distortion at the low frequency distortion threshold, this it may be increased. The generation of the equalization setting 28 will be described in greater detail with reference to FIGS. 3-8.

In yet another embodiment, the processing module 12 may utilize the signal level, the supply voltage 34, and/or the volume setting 30 to generate the equalization setting 28.

FIG. 3 is a graph of human perceptibility to an audio signal frequency spectrum. As shown, the audio signal spectrum ranges from approximately 20 hertz to approximately 20 kilohertz with, respect to the human ear, peaks at approximately 1 kilohertz. In order for the human ear to perceive frequencies at the outer edges of the audio signal spectrum at the same level as signals near 1 kilohertz, increased gains may be used. Such increased gain may potentially cause clipping in the audio output stage of the lower and higher frequency components of an audio signal. If the lower frequency signal components are clipped, distortion in the audio output occurs. In order to avoid the low distortion caused by clipping of the low frequency signal components of an audio signal, the processing module 12 generates the equalization setting 28 as previously discussed and as further illustrated in the examples of FIGS. 4-8.

FIG. 4 is a graph of the frequency spectrum of an example of the equalization setting 28 generated by the processing module 12 based on the volume setting 30 with respect to a range of volume settings 50. As shown, the frequency spectrum is divided into a low, mid and high range. Note that the frequency spectrum may be divided into more or less regions than three. In this example, when the volume level, with respect to the range of volume settings 50 is low, the equalization setting 28 is consistent (i.e., at the same level), throughout the frequency spectrum. Once the volume setting reaches the “volume setting threshold”, the lower range of the frequency spectrum is held at a lower gain setting than the gain setting of the mid and high ranges. As the volume setting increases above the volume setting threshold, the differential between the gain settings for the lower frequencies with respect to the mid and higher range frequencies is increased. With such an equalization setting 28, gain of the lower frequency components of the digital audio signal 24, the analog audio signal 26, and/or the amplified audio output 32 is controlled such that low frequency distortion is substantially avoided.

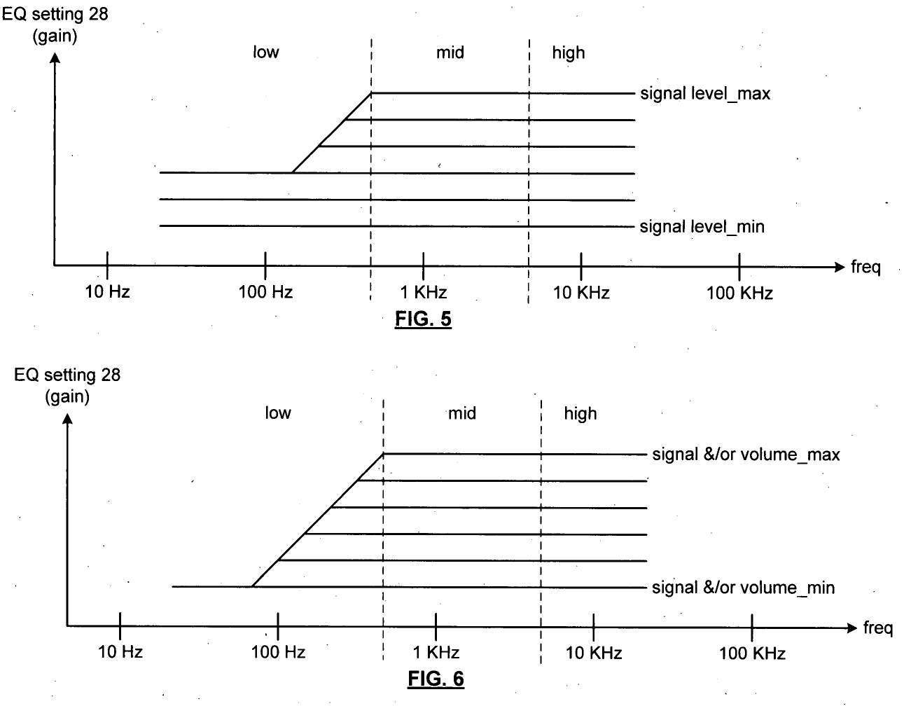

FIG. 5 is a graph of the frequency spectrum of another example of the equalization setting 28 generated by the processing module 12 based on the signal level of the digital audio signal 24 and/or the analog audio signal 26. In this embodiment, as long as the signal level of the digital or analog signal 24, 26 is below the low frequency distortion threshold, the equalization setting 28, or gain, is substantially constant throughout the frequency spectrum. Once the signal level reaches, or exceeds, the threshold, the gain of the lower frequency spectrum is held at a particular value while the gain for the mid and high range frequency spectrum are allowed to increase corresponding to the desired signal level. Note that a combination of the signal level and volume setting may be used to establish the equalization setting 28.

FIGS. 6 & 7 illustrate an example of adjusting the equalization setting 28 based on the supply voltage. Regardless of whether the equalization setting 28 was initially generated based on the volume setting 30 and/or the signal level, the processing module 12 may adjust the thresholds. For instance, as the supply voltage decreases, the potential for clipping of the lower frequency audio signal components is greater. Thus, the equalization setting 28 is adjusted to have the lower frequency component gain held at a lower level than the mid and high frequency ranges at a lower threshold as shown in FIG. 6. In this example, the reduction of the gain of the low frequency components of the equalization 28 is held low at a much lower threshold than in the examples of FIGS. 4 and 5.

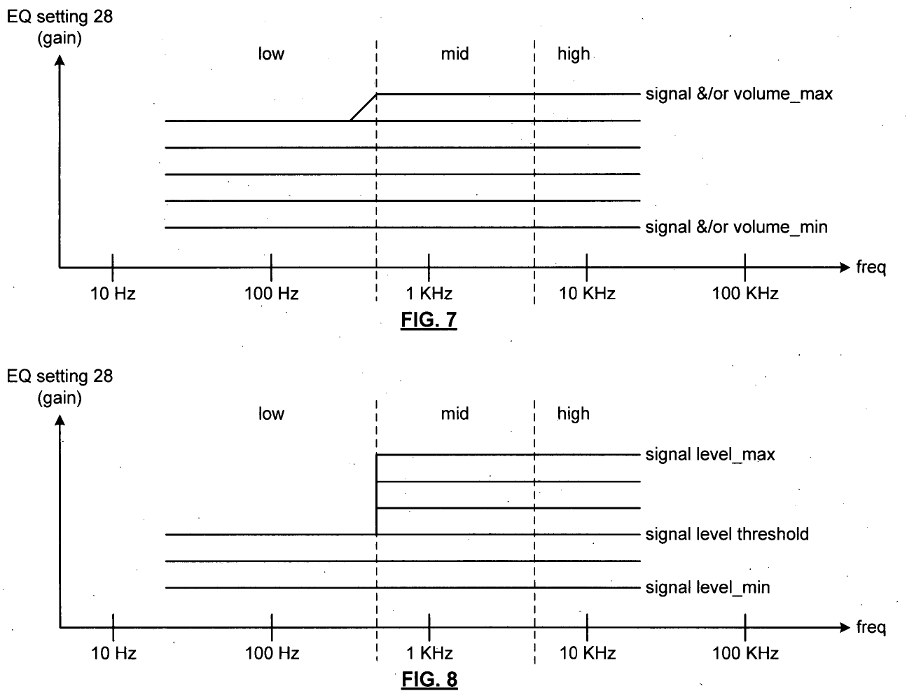

Conversely, when the supply voltage is greater, there is less chance of clipping of the lower frequency signal components. Accordingly, the gain of the lower frequency components of the equalization setting 28 can rise to higher levels before being held at a constant value to avoid clipping. An example of this is illustrated in FIG. 7.

FIG. 8 is yet another example of the equalization setting 28 being held at a particular constant value throughout the spectrum when the signal level, or the volume setting, exceeds a corresponding threshold. In this example, there is a sharp roll-off between the gain of the low frequency section and the mid frequency range section. Note that the examples of FIGS. 4-8 are merely examples and do not illustrate exact frequency responses. For example, the frequency response in the lower volume range does not have to be flat; it could be of any shape. Further, the corner frequencies for the lower frequency response changes could be at various frequencies and the roll off may be greater or less than illustrated. Further note that the equalization setting adjustment may to be used to avoid clipping of higher frequency signal components, but clipping of such components generally do not produce noticeable distortion.

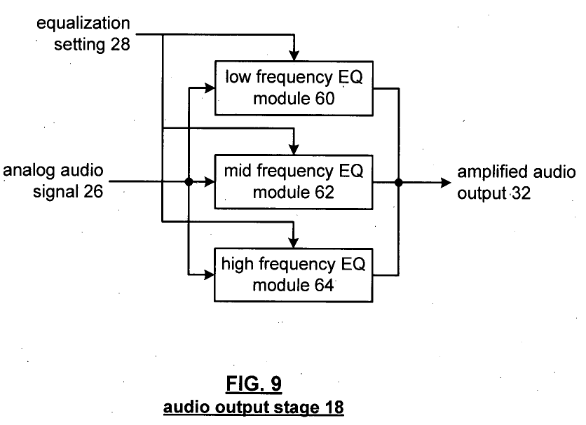

FIG. 9 is a schematic block diagram of an embodiment of the audio output stage 18. In this embodiment, the audio output stage 18 includes a low frequency equalization module 60, a mid frequency equalization module 62, and a high frequency equalization module 64. Each module 60-64 may include one or more amplifiers and/or drivers, wherein the gain of the module 60-64 is adjusted based on the corresponding frequency component section of the equalization setting 28 and amplifies the analog audio signal 24 accordingly. The outputs of the modules 60-64 are summed to produce the amplified audio output 32.

As one of ordinary skill in the art will appreciate, the term “substantially” or “approximately”, as may be used herein, provides an industry-accepted tolerance to its corresponding term and/or relativity between items. Such an industry-accepted tolerance ranges from less than one percent to twenty percent and corresponds to, but is not limited to, component values, integrated circuit process variations, temperature variations, rise and fulll times, and/or thermal noise. Such relativity between items ranges from a difference of a few percent to magnitude differences. As one of ordinary skill in the art will further appreciate, the term “operably coupled”, as may be used herein, includes direct coupling and indirect coupling via another component, element, circuit, or module where, for indirect coupling, the intervening component, element, circuit, or module does not modify the information of a signal but may adjust its current level, voltage level, and/or power level. As one of ordinary skill in the art will also appreciate, inferred coupling (i.e., where one element is coupled to another element by inference) includes direct and indirect coupling between two elements in the same manner as “operably coupled”. As one of ordinary skill in the art will further appreciate, the term “operably associated with”, as may be used herein, includes direct and/or indirect coupling of separate components and/or one component being embedded within another component. As one of ordinary skill in the art will still further appreciate, the term “compares favorably”, as may be used herein, indicates that a comparison between two or more elements, items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1.

The preceding discussion has presented various methods and apparatus for reducing and/or avoiding low frequency distortion caused by clipping of low frequency signal components in an audio device. As one of average skill in the art will appreciate, other embodiments may be derived from the teaching of the present invention without deviating from the scope of the claims.

What is claimed is:

1. A method comprises:
monitoring a volume setting of an audio signal with respect to a range of volume settings to produce a monitored volume setting; and
establishing an equalization setting based on the monitored volume setting.

2. The method of claim 1, wherein the establishing the equalization setting comprises:
determining whether low frequency distortion of the volume adjusted audio signal is possible based on the volume setting and the range of volume settings; and
when the low frequency distortion of the volume adjusted audio signal is possible, setting a low frequency range of the equalization setting at a level to avoid the low frequency distortion.

3. The method of claim 2 further comprises:
when the low frequency distortion of the volume adjusted audio signal is possible, setting at least one of mid and high frequency ranges of the equalization setting at a level above the level of the low frequency range of the equalization setting.

4. The method of claim 1, wherein the establishing the equalization setting comprises:
utilizing the volume setting as an index to a look up table; and
retrieving the equalization setting from the look up table.

5. The method of claim 1 further comprises:
monitoring a supply voltage to produce a monitored supply voltage; and
establishing the equalization setting based on the monitored volume setting and the monitored supply voltage.

6. The method of claim 1 further comprises:
monitoring a signal level of the audio signal to produce a monitored signal level; and
establishing the equalization setting based on the monitored volume setting and the monitored signal level.

7. The method of claim 1 further comprises:
amplifying the audio signal based on the monitored volume setting and the equalization setting.

8. A method comprises:
monitoring signal level of an audio signal;
determining whether the signal level compares unfavorably with a low frequency distortion threshold; and
when the signal level compares unfavorably to the low frequency distortion threshold, establishing an equalization setting to avoid low frequency distortion.

9. The method of claim 8, wherein the establishing the equalization setting comprises:
setting a low frequency range of the equalization setting at a level to avoid the low frequency distortion.

10. The method of claim 9, wherein the establishing the equalization setting further comprises:
setting at least one of mid and high frequency ranges of the equalization setting at a level above the level of the low frequency range of the equalization setting.

11. The method of claim 8 further comprises:
monitoring a supply voltage to produce a monitored supply voltage; and
adjusting the low frequency distortion threshold based on the monitored supply voltage.

12. The method of claim 8 further comprises:
comparing the signal level with a plurality of low frequency distortion thresholds, wherein the plurality of low frequency distortion thresholds include the low frequency distortion threshold;
determining a level of low frequency distortion based on the comparing of the signal level with the plurality of low frequency distortion thresholds; and
establishing the equalization setting based on the level of low frequency distortion.

13. An audio device comprises:
a processing module operably coupled to decode an audio file into a digital audio signal;
a digital to analog conversion module operably coupled to convert the digital audio signal into an analog audio signal; and
an audio output stage operably coupled to amplify the analog audio signal based on a volume setting and an equalization setting, wherein the processing module functions to:
monitor the volume setting of the analog audio signal with respect to a range of volume settings to produce a monitored volume setting; and
establish the equalization setting based on the monitored volume setting.

14. The audio device of claim 13, wherein the processing module establishes the equalization setting by:
determining whether low frequency distortion of the volume adjusted audio signal is possible based on the volume setting and the range of volume settings; and
when the low frequency distortion of the volume adjusted audio signal is possible, setting a low frequency range of the equalization setting at a level to avoid the low frequency distortion.

15. The audio device of claim 14, wherein the processing module further functions to:
when the low frequency distortion of the volume adjusted audio signal is possible, set at least one of mid and high frequency ranges of the equalization setting at a level above the level of the low frequency range of the equalization setting.

16. The audio device of claim 13, wherein the processing module establishes the equalization setting by:
utilizing the volume setting as an index to a look up table; and
retrieving the equalization setting from the look up table.

17. The audio device of claim 13, wherein the processing module functions to:
monitor a supply voltage to produce a monitored supply voltage; and
establish the equalization setting based on the monitored volume setting and the monitored supply voltage.

18. The audio device of claim 13, wherein the processing module functions to:
monitor a signal level of the audio signal to produce a monitored signal level; and
establish the equalization setting based on the monitored volume setting and the monitored signal level.

19. An audio device comprises:
a processing module operably coupled to decode an audio file into a digital audio signal;
a digital to analog conversion module operably coupled to convert the digital audio signal into an analog audio signal; and
an audio output stage operably coupled to amplify the analog audio signal based on a volume setting and an equalization setting, wherein the processing module functions to:
monitor signal level of the analog audio signal or of the digital audio signal;
determine whether the signal level compares unfavorably with a low frequency distortion threshold; and
when the signal level compares unfavorably to the low frequency distortion threshold, establish an equalization setting to avoid low frequency distortion.

20. The audio device of claim 19, wherein the processing module establishes the equalization setting by:
setting a low frequency range of the equalization setting at a level to avoid the low frequency distortion.

21. The audio device of claim 20, wherein processing module establishes the equalization setting by:
setting at least one of mid and high frequency ranges of the equalization setting at a level above the level of the low frequency range of the equalization setting.

22. The audio device of claim 19, wherein the processing module functions to:
monitor a supply voltage to produce a monitored supply voltage; and
adjust the low frequency distortion threshold based on the monitored supply voltage.

23. The audio device of claim 19, wherein the processing module functions to:
compare the signal level with a plurality of low frequency distortion thresholds, wherein the plurality of low frequency distortion thresholds include the low frequency distortion threshold;
determine a level of low frequency distortion based on the comparing of the signal level with the plurality of low frequency distortion thresholds; and
establish the equalization setting based on the level of low frequency distortion.
